(19) United States
(12) Patent Application Publication
(10) Pub. No.: US 2023/0068174 A1
(43) Pub. Date: Mar. 2, 2023

(54) SEMICONDUCTOR ETCHING DEVICE

(71) Applicant: CHANGXIN MEMORY TECHNOLOGIES, INC., Hefei City, Anhui (CN)

(72) Inventor: Chin-Kuan LIN, Hefei City, Anhui (CN)

(21) Appl. No.: 17/437,312

(22) PCT Filed: May 26, 2021
(86) PCT No.: PCT/CN2021/096194

§ 371 Date: Sep. 8, 2021

(30) Foreign Application Priority Data
Jun. 8, 2020 (CN) 202010514735.1

(51) Int. Cl. H01L 21/67

(52) U.S. Cl. CPC H01L 21/67063; H01L 21/67126; H01L 21/67242

(57) ABSTRACT

An embodiment of the present application provides a semiconductor etching device, comprising: an air delivery chamber (21), configured to accommodate a wafer (22) to be etched; an air intake module (23), configured to feed air into the air delivery chamber (21); an air exhaust module, configured to exhaust air in the air delivery chamber (21), the air exhaust module comprising an airlock (27) and a wind speed measurement and control unit (28), the wind speed measurement and control unit (28) being configured to detect an air flow rate in the air delivery chamber (21) and adjust the degree of opening of the airlock (27) based on the air flow rate.

### CROSS-REFERENCE TO RELATED APPLICATIONS

The present application claims the priority to Chinese Patent Application 202010514735.1, titled “SEMICONDUCTOR ETCHING DEVICE”, filed on Jun. 8, 2020, which is incorporated herein by reference in its entirety.

### TECHNICAL FIELD

Embodiments of the present application relate to the field of semiconductor manufacturing, and in particular, to a semiconductor etching device.

### BACKGROUND

At present, the microelectronics manufacturing technology is developing rapidly. The production lines for silicon wafers have been well established, and the line width of chips has reached the nanometer level. Therefore, for corresponding products, higher requirements on the production environment are proposed. For the microelectronics manufacturing industry, molecular air contaminants in the air (or airborne molecular contaminants, AMC for short) and particulates may do harm to products and directly lead to the reduction in yield.

In the current semiconductor processes, after the silicon wafer is etched in the etching chamber, there may be residual air on the surface of the silicon wafer. When the silicon wafer is transferred from the etching chamber of the semiconductor etching device to the air module of the semiconductor etching device, the residual air on the surface of the silicon wafer may react with air containing molecular air contaminants in the air module, so that condensation occurs during the reaction. The condensation may directly affect the yield of silicon wafers.

### SUMMARY

An embodiment of the present application provides a semiconductor etching device, comprising: an air delivery chamber, configured to accommodate a wafer to be etched; an air intake module, configured to feed air into the air delivery chamber ; an air exhaust module, configured to exhaust air in the air delivery chamber, the air exhaust module comprising an airlock and a wind speed measurement and control unit, the wind speed measurement and control unit being configured to detect an air flow rate in the air delivery chamber and adjust a degree of opening of the airlock based on the air flow rate.

### BRIEF DESCRIPTION OF THE DRAWINGS

One or more embodiments will be exemplified by pictures in the corresponding drawings. These exemplified descriptions do not constitute any limitation to the embodiments. Elements with the same reference numerals in the drawings are represented as similar. Unless otherwise stated, the drawings are not necessarily drawn to scale.

FIG. 1 is a schematic cross-sectional structure diagram of a semiconductor etching device according to the present application;

FIG. 2 is a schematic cross-sectional structure diagram of a semiconductor etching device according to a first embodiment of the present application; and

FIG. 3 is a schematic cross-sectional structure diagram of a semiconductor etching device according to a second embodiment of the present application.

### DETAILED DESCRIPTION

It may be known from the background that, after the silicon wafer is etched, the residual air on the surface of the silicon wafer may react with air containing molecular air contaminants, so that condensation occurs during the reaction. This phenomenon may directly affect the yield of silicon wafers.

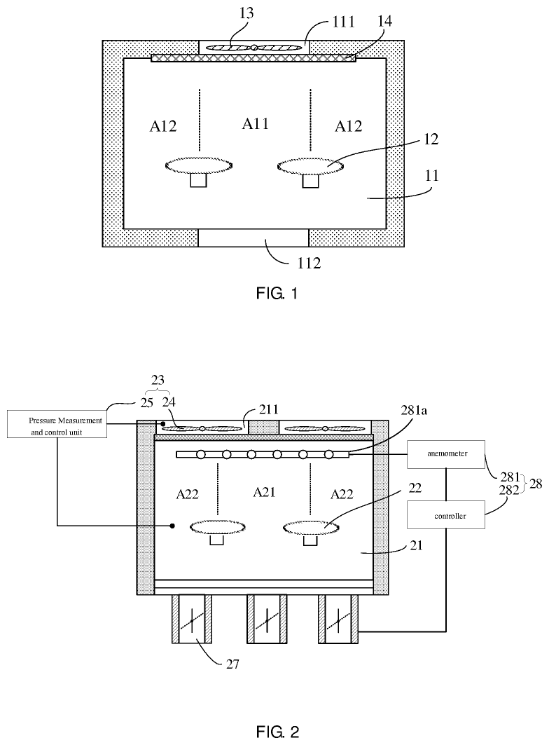

Referring to FIG. 1, the semiconductor etching device comprises: an air delivery chamber 11, configured to accommodate a wafer 12 to be etched. The air delivery chamber 11 has an air inlet 111 and an air outlet 112. An air filter 14 is provided on a side of the air inlet 111 to filter air flowing in from the air inlet 111 to a certain extent, so as to improve the cleanliness in the air delivery chamber 11.

Since the air delivery chamber 11 has only an air inlet 111, during wafer cleaning, air only in a first region All corresponding to the air inlet 111 can flow in an orderly manner at the air feed rate. The orderly and fast-flowing air can take air contaminants (including air molecular contaminants carried by the fed air and residual air on the surface of the wafer 12) away from the air delivery chamber 11 timely and effectively.

Meanwhile, due to the viscosity of the fluid movement, the air flow rate in a second region A12 is less than the air flow rate in the first region A11. As a result, the air contaminants in the second region A12 cannot be taken away from the air delivery chamber 11. The air contaminants in the second region A12 stay in the air delivery chamber 11 for a longer period of time. Consequently, the air molecular contaminants may react with the residual air on the surface of the wafer 12, thereby forming condensation defects on the surface of the wafer 12 and thus reducing the product yield.

At present, the air outlet 112 is connected to the inside and outside of the air delivery chamber 11. The change of the external pressure will affect the air flow rate in the air delivery chamber 11 and the pressure inside the air delivery chamber 11, thereby affecting the cleanliness in the air delivery chamber 11. Specifically:

The air flow rate in the air delivery chamber 11 depends upon the pressure difference between the inside and outside of the air delivery chamber 11. The larger the pressure difference, the higher the air flow rate. Since the pressure inside the air delivery chamber 11 is positive relative to the pressure outside, when the pressure outside the air delivery chamber 11 decreases, the pressure difference between the inside and outside of the air delivery chamber 11 increases, and the air flow rate in the air delivery chamber 11 increases.

The air flow changes from laminar flow to turbulent flow when the air flow rate in the air delivery chamber 11 exceeds the flow rate threshold. That is, the orderly flowing changes to disorderly flowing. As a result, the air flow is unable to quickly take the air contaminants away from the air delivery chamber 11. Instead, due to the turbulent flow, the air contaminants may stay in the air delivery chamber 11 for a longer period of time, and the air molecular contaminants may be in full contact with the residual air on the surface of the wafer 12. Consequently, the residual air on the surface of the wafer 12 reacts with the air molecular contaminants in the air delivery chamber 11 to result in condensation which affects the product yield.

In addition, as the external pressure decreases, the pressure inside the air delivery chamber 11 may also decrease, and the decrease of the pressure inside the air delivery chamber 11 may cause the external air to flow back to reduce the cleanliness in the air delivery chamber 11.

For example, before the external pressure decreases, the external pressure may be regarded as one standard atmospheric pressure, and the internal pressure may be regarded as 1.1 times the standard atmospheric pressure. After the external pressure decreases, the internal pressure decreases accordingly. For example, when the external pressure decreases to 0.5 times the standard atmospheric pressure, the internal pressure may decrease to 0.6 times the standard atmospheric pressure. In this case, when the external pressure suddenly returns to the standard atmospheric pressure, it may be possible that the external air flows back to the air delivery chamber 11 since the external pressure is greater than the internal pressure, thereby reducing the cleanliness in the air delivery chamber 11.

Correspondingly, when the external pressure increases, the pressure difference between the inside and outside of the air delivery chamber 11 decreases, and the air flow rate in the air delivery chamber 11 decreases. The decrease of the air flow rate will cause the air flow to be unable to take away the residual air on the surface of the wafer 12 and the air molecular contaminants at a high rate. As a result, the surface residual air and the air molecular contaminants stay in the air delivery chamber 11 for an increased period of time. The surface residual air is more likely to react with the air molecular contaminants in the air delivery chamber 11 to cause condensation defects, resulting in a decreased product yield.

In order to solve the above technical problems, an embodiment of the present application provides a semiconductor etching device. The wind speed measurement and control unit can adjust the degree of opening of the airlock when the air flow rate in the air delivery chamber exceeds the flow rate threshold. This reduces the impact on the air flow in the air delivery chamber by the air flow rate change, prevents the air contaminants from staying for an increased period of time due to the reduced air flow rate or turbulent flow, ensures that the air contaminants in the air delivery chamber can be taken away timely and effectively, and improves the cleanliness in the air delivery chamber.

To make the objectives, technical solutions and advantages of the embodiments of the present application clearer, the embodiments of the present application will be further described below in detail with reference to the accompanying drawings. However, it may be understood by a person of ordinary skill in the art that, in the embodiments of the present application, many technical details are provided for the better understanding of the present application. However, the technical solutions sought to be protected by the present application can be implemented, even without these technical details and various changes and modifications based on the following embodiments.

FIG. 2 is a schematic cross-sectional structure diagram of a semiconductor etching device according to an embodiment of the present application.

Referring to FIG. 2, the semiconductor etching device comprises: an air delivery chamber 21, configured to accommodate a wafer 22 to be etched; an air intake module 23, configured to feed air into the air delivery chamber 21; an air exhaust module, configured to exhaust air in the air delivery chamber 21, the air exhaust module comprising an airlock 27 and a wind speed measurement and control unit 28, the wind speed measurement and control unit 28 being configured to detect an air flow rate in the air delivery chamber 21 and adjust the degree of opening of the airlock 27 based on the air flow rate.

In this embodiment, the air delivery chamber 21 comprises at least two air inlets 211, the air intake module 23 feeds air into the air delivery chamber 21 through the air inlets, each air inlet 211 corresponding to a laminar flow region. In this way, it is helpful to expand the range of the laminar flow region in the air delivery chamber 21, so that the air contaminants in a larger range can be effectively taken away from the air delivery chamber 21 by the air flow in time, to ensure the cleanliness in the air delivery chamber 21 and to improve the product yield.

In this embodiment, the degree of opening of the airlock 27 is greater than 0 and less than 100% in the initial state. In this way, the wind speed measurement and control unit 28 can reduce or increase the degree of opening of the airlock 27 when the air flow rate in the air delivery chamber 21 changes, so as to reduce or increase the air flow rate in the air delivery chamber 21. This enables the air flow to take the air contaminants away from the air delivery chamber 21 at a high rate without forming turbulent flow, and improves the cleanliness in the air delivery chamber 21.

It should be noted that there are many factors influencing the air flow rate, including but not limited to: since the airlock 27 is driven by mechanical power, when the power source fails and the degree of opening of the airlock changes, the air flow rate in the air delivery chamber 21 changes; or, since the airlock 27 is communicated with the inside and outside of the air delivery chamber 21, when the pressure outside the air delivery chamber 21 changes, the air flow rate changes accordingly.

Since the airlock 27 is communicated with the inside and outside of the air delivery chamber 21, in order to ensure that air in the air delivery chamber 21 can smoothly flow out through the airlock 27, the pressure inside the air delivery chamber 21 needs to be greater than the pressure outside the air delivery chamber 21. Taking the pressure outside the air delivery chamber 21 being one standard atmospheric pressure as an example, the pressure inside the air delivery chamber 21 needs to be greater than one standard atmospheric pressure, that is, the pressure inside the air delivery chamber 21 needs to be positive. Meanwhile, in order to ensure that the pressure inside the air delivery chamber 21 is within the preset flow rate threshold, and to avoid the air backflow caused when the external pressure suddenly increases after a pressure drop, the pressure inside the air delivery chamber 21 should be greater than one standard atmospheric pressure and less than a pressure value. In this way, the air flow rate that changes based on the pressure difference between the inside and outside of the air delivery chamber 21 is within the preset flow rate threshold.

The pressure difference between the inside and outside of the air delivery chamber 21 may be set as 0.0 in.wc to 0.1 in.wc, for example, 0.03 in.wc, 0.06 in.wc, 0.09 in.wc. The flow rate threshold may be set as 85 FPM to 90 FPM, for example, 86 FPM, 87 FPM, 88 FPM.

In this embodiment, the air intake module 23 comprises a pressure measurement and control unit 25 and an air flow adjustment unit 24, and the pressure measurement and control unit 25 is configured to detect pressure in the air delivery chamber 21 and control the air flow adjustment unit 24 to adjust the air feed rate based on the pressure. The pressure measurement and control unit 25 is configured to control the air flow adjustment unit 24 to adjust the air feed rate when the pressure exceeds the pressure threshold.

In this embodiment, the air flow adjustment unit 24 comprises at least two fans placed in the air inlets 211, with one fan being accommodated in each air inlet 211. By providing multiple fans to feed air separately, it is helpful to improve the uniformity of the air flow rate in different regions in the air delivery chamber 21, and avoid the turbulent flow caused by the non-uniform flow rate. Therefore, the flowing air can take the air contaminants away timely and effectively.

The basic working principle of the wind speed measurement and control unit 28 will be described in detail below according to the semiconductor etching device in this embodiment. Specifically:

When the pressure outside the air delivery chamber 21 decreases, the pressure difference between the inside and outside of the air delivery chamber 21 increases, and the air flow rate in the air delivery chamber 21 increases. In this case, the wind speed measurement and control unit 28 reduces the degree of opening of the airlock 27, so that the air outflow amount from the air delivery chamber 21 is the same as the air outflow amount before the external pressure decreases. Therefore, the internal pressure is kept stable. Meanwhile, due to the constant air outflow amount, the air flow rate in the air delivery chamber 21 returns to the level before the air flow rate increases. That is, the air flow in the air delivery chamber 21 is still laminar flow.

In this way, it is helpful to avoid the turbulent flow caused by the increase of the air flow rate, so that the air flow can effectively take the air contaminants away from the air delivery chamber 21 in time. The cleanliness in the air delivery chamber 21 is improved, and the reaction of the residual air on the surface of the wafer 22 with the air molecular contaminants in the air delivery chamber 21 is avoided. The damage to the surface of the wafer 22 by the condensation is avoided, and the product yield is improved.

In this embodiment, the airlock 27 comprises a plurality of valves arranged uniformly and in parallel along the air outflow direction. The change in the air flow rate at different positions in the air delivery chamber 21 is related to the distance from the valve. When the external pressure decreases, the increase in the air flow rate near the valve is greater than the increase in the air flow rate far away from the valve. By uniformly providing a plurality of valves in parallel, the difference in the air flow rate change at different positions in the air delivery chamber 21 may be made small. That is, the air flow rate in the air delivery chamber 21 has better uniformity. In this way, it is helpful to avoid the turbulent flow caused by the non-uniform air flow rate, ensure that the flowing air can timely and effectively take the air contaminants away from the air delivery chamber 21, and ensure the cleanliness in the air delivery chamber 21.

When the pressure outside the air delivery chamber 21 increases, the pressure difference between the inside and outside of the air delivery chamber 21 decreases, and the air flow rate in the air delivery chamber 21 decreases. In this case, the wind speed measurement and control unit 28 increases the degree of opening of the airlock 27, so that the air outflow amount from the air delivery chamber 21 remains unchanged. In this way, the air contaminants are prevented from staying in the air delivery chamber 21 for a long period of time due to the reduction of the air outflow amount. The air contaminants can be taken away timely and effectively and high cleanliness in the air delivery chamber 21 is ensured.

It is to be noted that, in this embodiment, since the air intake module 23 always feeds air, with the increase in the external pressure, the pressure inside the air delivery chamber 21 increases as the air outflow rate decreases or becomes zero. When the increase rate of the pressure outside the air delivery chamber 21 is less than or equal to the air feed rate of the air intake module 23, the pressure inside the air delivery chamber 21 is greater than the pressure outside the air delivery chamber 21. The expression “the increase in the external pressure” in this embodiment means that the pressure outside the air delivery chamber 21 increases, the pressure inside the air delivery chamber 21 remains unchanged, and the increased external pressure is still less than the pressure inside the air delivery chamber 21. In this embodiment, the air inlet 211 and the airlock 27 are located on two opposite sides of the air delivery chamber 21. In this way, the flow path of the air from the inflow to the outflow is almost straight. It is helpful to avoid the turbulent flow caused by the need for the air to flow in a curve, thereby ensuring that the air contaminants are taken away by the airflow, and improving the cleanliness in the air delivery chamber 21.

In this embodiment, the wind speed measurement and control unit 28 comprises an anemometer 281 and a controller 282. A sensing unit 281a of the anemometer 281 is configured to detect the air flow rate in the air delivery chamber 21. The sensing unit 281a is located on a side of the air delivery chamber 21 far from the air outlet. The controller 282 is configured to control the degree of opening of the airlock 27 based on the detection result of the anemometer 281.

When the external pressure decreases, the air in a region of the air delivery chamber 21 close to the airlock 27 (hereinafter referred to as an air exhaust region) flows faster first due to the increased pressure difference. The flow rate in the region far from the airlock 27 (hereinafter referred to as an air intake region) does not change, when the air outflow rate in the air exhaust region increases. As a result, the pressure in the air exhaust region decreases due to the delayed supplementation of air. The air in the air intake region flows faster due to the increased pressure difference between the air intake region and the air exhaust region, only when the pressure in the air exhaust region decreases.

When there is only an instantaneous change in the external pressure, the decrease in pressure in the air exhaust region due to the increase in the air flow rate is negligible. Thus, the change in the flow rate of the air in the air intake region due to the pressure difference is negligible or may be considered as normal air flow rate fluctuation. That is, the air flow rate at the location of the anemometer 281 will not change significantly. Therefore, there is no need to frequently adjust the degree of opening of the airlock 27 due to the frequent and instantaneous change in the external pressure. In other words, when the anemometer 281 detects a change in the air flow rate at its location, it is indicated that the change in the external pressure has caused a significant change in the pressure in the air exhaust region. That is, the change in the external pressure is not instantaneous. In this case, the controller 282 adjusts the degree of opening of the airlock 27. In this way, it is helpful to reduce the frequency of adjustment of the airlock 27 and increase the operating life.

In this embodiment, the wind speed measurement and control unit 28 can adjust the degree of opening of the airlock 27 when the air flow rate in the air delivery chamber 21 exceeds the flow rate threshold, thereby reducing the impact on the air flow rate in the air delivery chamber 21 by the decrease in the external pressure. It is helpful to avoid the turbulent flow in the air delivery chamber 21. Thus, the air contaminants can be effectively exhausted, and the cleanliness in the air delivery chamber 21 is improved.

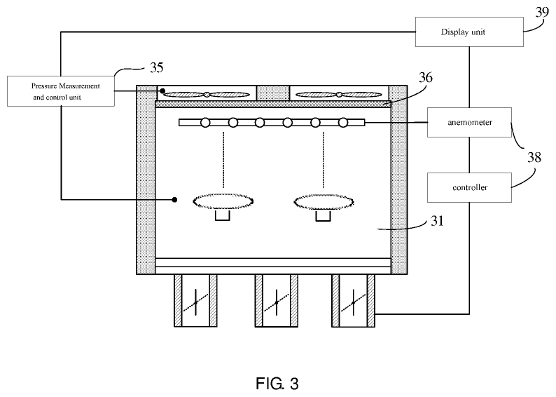

Another embodiment of the present application further provides a semiconductor etching device. The difference from the previous embodiment is that this embodiment further comprises a display module and an air filter device. The detailed description will be given below with reference to FIG. 3, which is a schematic cross-sectional structure diagram of the semiconductor etching device according to the second embodiment of the present application. For the parts that are the same as or corresponding to the previous embodiment, please refer to the corresponding description of the previous embodiment. They will not be described in detail below.

In this embodiment, the semiconductor etching device further comprises: a display module 39, respectively connected to the wind speed measurement and control unit 38 and the pressure measurement and control unit 35. The content displayed by the display module 39 comprises the pressure in the air delivery chamber 31 and/or the air flow rate in the air delivery chamber 31. In this way, the staff can timely adjust the degree of opening of the airlock, the air feed rate and the specific settings of other devices related to the semiconductor etching device based on the content displayed by the display module 39, to ensure the cleanliness in the air delivery chamber 31.

In this embodiment, the air intake module further comprises an air filter device 36. The air filter device is a high-efficiency air particle filter or an ultra-high-efficiency air particle filter. The filter element of the air filter device 36 may be made of glass fiber, foam plastic and other materials. When the filter element is made of glass fiber, the filter efficiency of the air filter device 36 is related to the thickness of the glass fiber. The finer the glass fiber is, the higher the filter efficiency is.

In this embodiment, the use of the display module 39 helps the staff to identify the working status of the semiconductor etching device and adjust the settings and external conditions of the semiconductor etching device based on the working status to ensure the cleanliness in the air delivery chamber 31.

It may be understood by a person of ordinary skill in the art that the above-mentioned implementations are specific embodiments for realizing the present application, and in actual applications, various changes may be made to the form and details without departing from the spirit and scope of the present application. Those skilled in the art can make their own changes and modifications without departing from the spirit and scope of the present application. Therefore, the protection scope of the present application shall be subject to the scope defined by the claims.

1. A semiconductor etching device, comprising:
an air delivery chamber, configured to accommodate a wafer to be etched;
an air intake module, configured to feed air into the air delivery chamber; and
an air exhaust module, configured to exhaust air in the air delivery chamber, the air exhaust module comprising an airlock and a wind speed measurement and control unit, the wind speed measurement and control unit being configured to detect an air flow rate in the air delivery chamber and adjust a degree of opening of the airlock based on the air flow rate.

2. The semiconductor etching device according to claim 1, wherein the air intake module further comprises a pressure measurement and control unit and an air flow adjustment unit, and the pressure measurement and control unit is configured to detect pressure in the air delivery chamber and control the air flow adjustment unit to adjust the air feed rate based on the pressure.

3. The semiconductor etching device according to claim 2, wherein the pressure measurement and control unit is configured to control the air flow adjustment unit to adjust the air feed rate when the pressure exceeds a pressure threshold.

4. The semiconductor etching device according to claim 3, wherein the pressure threshold is 0.0 in.wc to 0.1 in.wc.

5. The semiconductor etching device according to claim 2, wherein the air delivery chamber comprises at least two air inlets, the air intake module feeds air into the air delivery chamber through the air inlets, each air inlet corresponding to a laminar flow region.

6. The semiconductor etching device according to claim 5, wherein the air flow adjustment unit comprises at least two fans placed in the air inlets, with one fan being accommodated in each air inlet.

7. The semiconductor etching device according to claim 2, wherein the wind speed measurement and control unit comprises an anemometer configured to detect the air flow rate in the air delivery chamber and a controller configured to adjust the degree of opening of the airlock when the air flow rate exceeds a flow rate threshold.

8. The semiconductor etching device according to claim 7, wherein the anemometer is located at an air inlet of the air delivery chamber.

9. The semiconductor etching device according to claim 7, wherein the flow rate threshold ranges from 85 FPM to 90 FPM.

10. The semiconductor etching device according to claim 2, further comprising: a display module respectively connected to the wind speed measurement and control unit and the pressure measurement and control unit, content displayed by the display module comprising the pressure in the air delivery chamber and/or the air flow rate in the air delivery chamber.

11. The semiconductor etching device according to claim 1, wherein the degree of opening of the airlock ranges from 0% to 100%.
